(19) United States
(12) Patent Application Publication
(10) Pub. No.: US 2025/0279132 A1
(43) Pub. Date: Sep. 4, 2025

(54) MULTIPLEXER AND MEMORY DEVICE INCLUDING THE SAME

(71) Applicant: SAMSUNG ELECTRONICS CO., LTD., Suwon-si (KR)

(72) Inventors: Hoseok Seol, Suwon-si (KR); Ki-Heung Kim, Suwon-si (KR); Hyongryol Hwang, Suwon-si (KR)

(21) Appl. No.: 19/030,221

(22) Filed: Jan. 17, 2025

(30) Foreign Application Priority Data
Feb. 29, 2024 (KR) 10-2024-0030007

(51) Int. Cl. G11C 11/4091; G11C 11/408; G11C 11/4093

(52) U.S. Cl. CPC G11C 11/4091; G11C 11/4087; G11C 11/4093

(57) ABSTRACT

A multiplexer includes a plurality of I/O sense amplifiers and a logic circuit. Each of the I/O sense amplifiers is configured to amplify and output normal data and metadata. The logic circuit is connected to the output terminals of the plurality of I/O sense amplifiers and is configured to output the metadata through a logical operation.

### CROSS-REFERENCE TO RELATED APPLICATION

This U.S. non-provisional application claims priority under 35 USC § 119 to Korean Patent Application No. 10-2024-0030007, filed on Feb. 29, 2024, in the Korean Intellectual Property Office, the disclosure of which is herein incorporated by reference in its entirety.

### BACKGROUND

Semiconductor memory devices may be classified into volatile memory devices and nonvolatile memory devices. Volatile memory devices lose their stored data when their power supplies are interrupted. A dynamic random access memory (DRAM), a type of volatile memory device, is used in various fields such as mobile systems, servers, or graphics devices.

### SUMMARY

Example implementations provide a multiplexer for multiplexing metadata and a memory device including the same.

According to example implementations, a multiplexer includes a plurality of input/output sense amplifiers, each configured to amplify and output normal data and metadata, and a logic circuit connected to output terminals of the plurality of input/output sense amplifiers and configured to output the metadata through a logical operation.

According to example implementations, a memory device includes a plurality of banks, each comprising a memory cell array and a column decoder, and a control logic circuit configured to provide a column address to the column decoder. The column decoder may include an input/output sense amplifier stage configured to amplify and output normal data and metadata provided from a selected column select line, among a plurality of column select line connected to the memory cell array, in response to the column address, and a logic stage connected to an output terminal of the input/output sense amplifier stage and configured to output the metadata through a logical operation.

According to example implementations, a memory device includes a plurality of banks, each comprising a memory cell array and a column decoder, and a data multiplexer configured to multiplex normal data output from the plurality of banks. The column decoder may include an input/output sense amplifier stage configured to amplify and output the normal data and metadata provided from a selected common select line, among a plurality of column select lines connected to the memory cell array, and a logic stage connected to an output terminal of the input/output sense amplifier stage and configured to output only the metadata through a logical operation.

### BRIEF DESCRIPTION OF DRAWINGS

FIG. 1 is a diagram illustrating a memory system according to example implementations.

FIG. 2 is a diagram illustrating a memory device according to example implementations.

FIG. 3 is a diagram illustrating a memory device according to example implementations.

FIG. 4 is a diagram illustrating a bank according to example implementations.

FIG. 5 is a diagram illustrating a bank array according to example implementations.

FIGS. 6 to 8 are diagrams illustrating a metadata multiplexer according to example implementations.

FIG. 9 is a diagram illustrating a combination of outputs of input/output sense amplifiers included in a metadata multiplexer according to example implementations.

FIG. 10 is a flowchart illustrating a method of operating a memory device according to example implementations.

FIG. 11 is a diagram illustrating a system according to example implementations.

### DETAILED DESCRIPTION

Hereinafter, example implementations will be described with reference to the accompanying drawings.

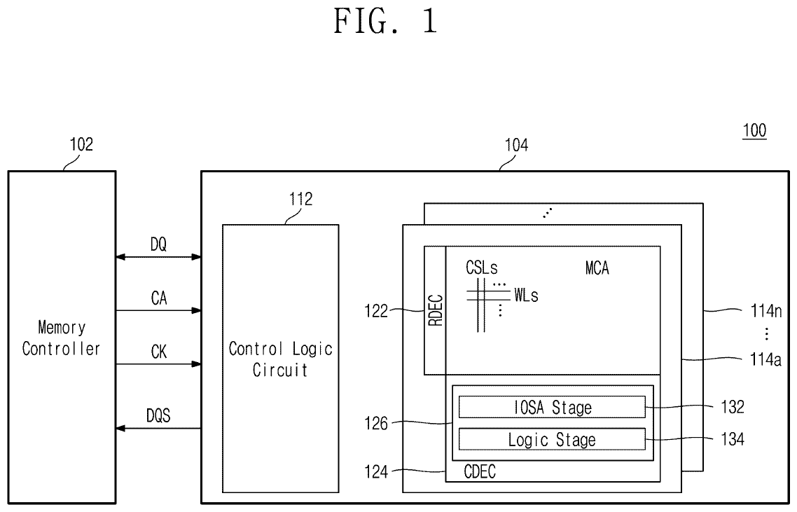

FIG. 1 is a diagram illustrating a memory system according to example implementations.

Referring to FIG. 1, a memory system 100 according to example implementations may include a memory controller 102 and a memory device 104.

The memory controller 102 may control the overall operation of the memory system 100, and may control data exchange between a host device, connected to the memory system 100, and the memory device 104. The memory controller 102 may control the memory device 104 in response to a request from the host device to write or read data.

The memory controller 102 may generate a command/address signal CA to access the memory device 104 in response to operations executed by the host device. The memory controller 102 may access the memory device 104 through the command/address signal CA. The memory controller 102 may be connected to the memory device 104 through a plurality of channels including buses or signal lines. According to example implementations, the memory controller 102 may be connected to the memory device 104 through a plurality of channels including a plurality of sub-channels and may transmit and/or receive a command/address signal CA, a clock signal CK, a data signal DQ, and a data strobe signal DQS through the channels.

For example, the memory controller 102 may transmit and receive a data signal DQ to be written in the memory device 104 or a data signal DQ read from the memory device 104 according to the command/address signal CA. The memory controller 102 may receive the data strobe signal DQS corresponding to the data signal DQ from the memory device 104.

According to example implementations, the memory controller 102 may control the memory device 104 to write or read normal data and metadata in or from the memory device 104. The metadata may be defined as data used to improve performance or enhance security of the memory device 104. For example, the memory controller 102 may generate and transmit a command/address signal CA to read the metadata and receive a data signal DQ corresponding to the metadata from the memory device 104.

The memory controller 102 may control the memory device 104 in specific operation mode for reading metadata (hereinafter referred to as “meta mode”) to read metadata, together with normal data, from the memory device 104. The data signal DQ may include the normal data and the metadata.

The memory device 104, connected to the memory controller 102, may include a control logic circuit 112 and a plurality of banks 114a to 114n.

The control logic circuit 112 may control the operation of the memory device 104. The control logic circuit 112 may receive command/address signals CA from the memory controller 102 and generate an internal command, a mode register set signal, an address signal, or the like, to control the inside of the memory device 104 based on the received command/address signals CA. For example, the internal command may include an internal read command and an internal write command, and the address signal may include a bank address, a row address, and a column address.

Each of the plurality of banks 114a to 114n may include a memory cell array MCA, a row decoder 122, and a column decoder 124. The memory cell array MCA may include a plurality of memory cells. Each of the memory cells may store data (for example, 1 bit). The memory cell array MCA may be connected to a plurality of wordlines WLs and a plurality of column select lines CSLs, and a plurality of memory cells may be connected to each of the wordlines WLs and each of the common select lines CSLs. Memory cells connected to a wordline WL may be referred to as a row, and memory cells selected by a common select line CSL may be referred to as a column (or a sub-array).

According to example implementations, at least a portion of the plurality of wordlines WLs and a plurality of column select lines CLs may be assigned for metadata. The wordline and/or the common select line assigned for metadata may be enabled through the control logic circuit 112. For example, the control logic circuit 112 may provide a row address corresponding to the wordline assigned for metadata to the row decoder 122 through an address signal, and the row decoder 122 may decode the row address to enable a wordline corresponding to the row address. For example, the control logic circuit 112 may provide a column address corresponding to the column address line assigned for metadata to the column decoder 124 through an address signal, and the column decoder 124 may decode the column address to enable a column select line corresponding to the column address.

According to example implementations, in meta mode, the control logic circuit 112 may enable at least portion of the column select lines CSL assigned for metadata, while disabling the remaining column select lines CSL. These enabled column select lines CSL may enable transmission of the metadata.

According to example implementations, the column decoder 124 may include a multiplexer stage 126 including an input/output sense amplifier (IOSA) stage 132 and a logic stage 134. The multiplexer stage 126 may be implemented inside the column decoder 124 and may be configured to multiplex metadata read from the memory cell array MCA. For example, the multiplexer stage 126 may perform multiplexing using the input/output sense amplifier stage 132 configured to amplify and output data.

The input/output sense amplifier stage 132 may be configured to amplify and output data output from the memory cell array MCA. For example, the input/output sense amplifier stage 132 may be configured to amplify and output normal data and metadata provided from a column select line CSL selected in response to a column address, among a plurality of column select lines CSLs connected to the memory cell array MCA. The data, amplified and output through the input/output sense amplifier stage 132, may be provided to the memory controller 102 from the memory device 104 through the data signal DQ. According to example implementations, the input/output sense amplifier stage 132 may include a plurality of input/output sense amplifiers connected to a plurality of global input/output lines corresponding to the column select line CSL.

The input/output sense amplifier stage 132 may amplify and output normal data. Alternatively, the input/output sense amplifier stage 132 may amplify and output normal data and metadata in the above-described meta mode. For example, the input/output sense amplifier stage 132 included in the first bank 114a may amplify and output normal data, and the input/output sense amplifier stage 132 included in the nth bank 114n (where n is a positive integer greater than or equal to 2) may output metadata and a default value. The default value is a value output by the input/output sense amplifier stage 132 in response to a disabled column select line CSL and may be, for example, a value corresponding to a low level (or a high level).

The logic stage 134 may be connected to an output terminal of the input/output sense amplifier stage 132 and may be configured to output only metadata through a logical operation. For example, the logic stage 134 may be configured to perform a logical operation to select only metadata from among the metadata and default value output from the input/output sense amplifier stage 132. According to example implementations, the logic stage 134 may include a plurality of logic circuits, each corresponding to a single column.

As a result, the multiplexer stage 126 may multiplex and output only the metadata from among the metadata and default value through the input/output sense amplifier stage 132 and the logic stage 134.

According to the above-described implementations, the memory system 100 may use the input/output sense amplifier stage 132, included in the column decoder 124, as a multiplexer stage 126 for multiplexing metadata. For example, the memory system 100 may reduce a chip size using the input/output sense amplifier stage 132, included in the column decoder 124, as a multiplexer stage 126 for metadata without providing an additional multiplexer stage 126 for metadata in the input/output area of the memory device 104.

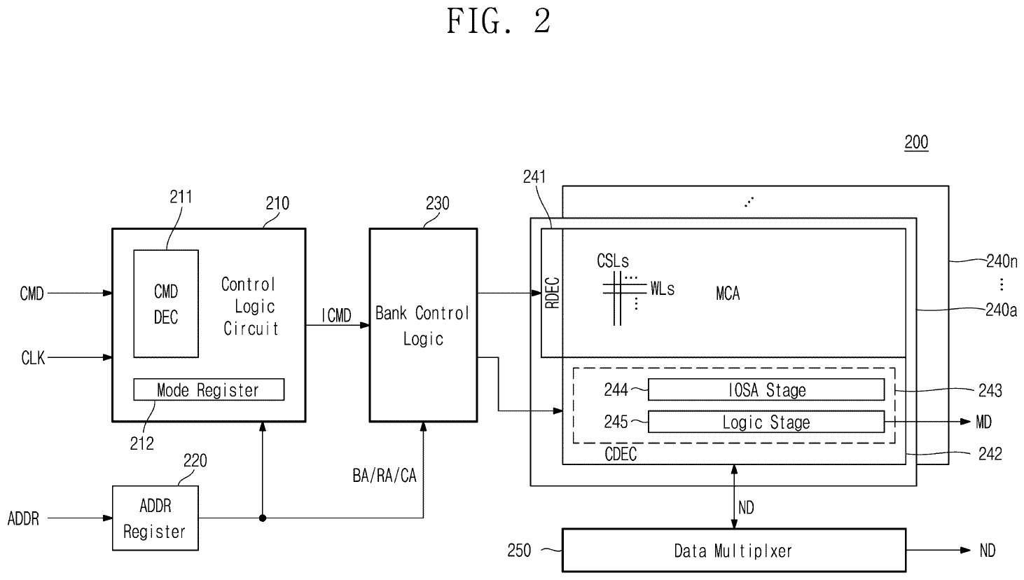

FIG. 2 is a diagram illustrating a memory device according to example implementations.

Referring to FIG. 2, a memory device 200 according to example implementations may include a control logic circuit 210, an address register 220, a bank control logic 230, a plurality of banks 240a to 240n, and a data multiplexer 250.

The control logic circuit 210 may control the operation of the memory device 200. For example, the control logic circuit 210 may receive a command CMD and a clock signal CLK from the memory controller described above in FIG. 1. The control logic circuit 210 may include a command decoder 211 decoding the received command CMD and a mode register 212 setting operation mode of the memory device 200. The command decoder 211 may decode a chip select signal, a command/address signal, or the like, and generate a control signal or internal command signals ICMDs corresponding to the command CMD. The generated internal command signals ICMDs may be transmitted to the bank control logic 230.

The address register 220 may receive an address signal ADDR, including a bank address BA, a row address RA, and a column address CA, from the memory controller of FIG. 1. The address register 220 may provide the bank address BA, the row address RA, and the column address CA, included in the received address signals ADDR, to the bank control logic 230.

The bank control logic 230 may be enabled based on the bank address BA. The enabled bank control logic 230 may generate bank control signals in response to the internal command signals ICMDs and the row address RA and column address CA. A row decoder 241 and a column decoder 242, connected to the memory cell array MCA corresponding to a specific bank, may be enabled in response to the bank control signals.

The enabled row decoder 241 may decode the row address RA to enable a wordline corresponding to the row address RA, among a plurality of wordlines WLs. For example, the enabled row decoder 241 may apply a wordline driving voltage to the wordline corresponding to the row address RA. In addition, the enabled column decoder 242 may enable an input/output sense amplifier corresponding to the bank address BA and column address CA.

According to example implementations, in meta mode, one of the plurality of banks 240a to 240n may be enabled based on the bank address BA and the row decoder 241 and column decoder 242, included in the enabled bank, may be enabled based on the row address RA and column address CA. The enabled row decoder 241 may enable a wordline corresponding to the row address RA, and the enabled column decoder 242 may enable a column select line CSL corresponding to the column address CA, among the plurality of column select lines CLSs. The remaining column select lines CSLs, other than the enabled column select line CSL, may be disabled. The remaining disabled column select lines CSLs may be considered to be masked.

An input/output sense amplifier stage 244, included in the column decoder 242, may amplify and output metadata MD corresponding to the enabled column select line CSL, and output a default value corresponding to the remaining disabled column select lines CSLs. A logic stage 245 may select and output only metadata MD from among the metadata MD and the default value output from the input/output sense amplifier stage 244 through a logical operation. Accordingly, the multiplexer stage 243 including the input/output sense amplifier stage 244 and the logic stage 245 may select and output metadata MD from a single bank.

In addition, the input/output sense amplifier stage 244 may amplify and output normal data ND other than metadata. The data multiplexer 250 may multiplex the normal data ND output from the input/output sense amplifier stages 244 included in the multiple banks 240a to 240n, and may output the normal data ND.

According to the above-described implementations, the memory device 200 may reduce a chip size using the input/output sense amplifier stage 244 included in the column decoder 242 as a multiplexer stage 243 for metadata MD without providing an additional multiplexer for metadata MD in an input/output area of the memory device 200.

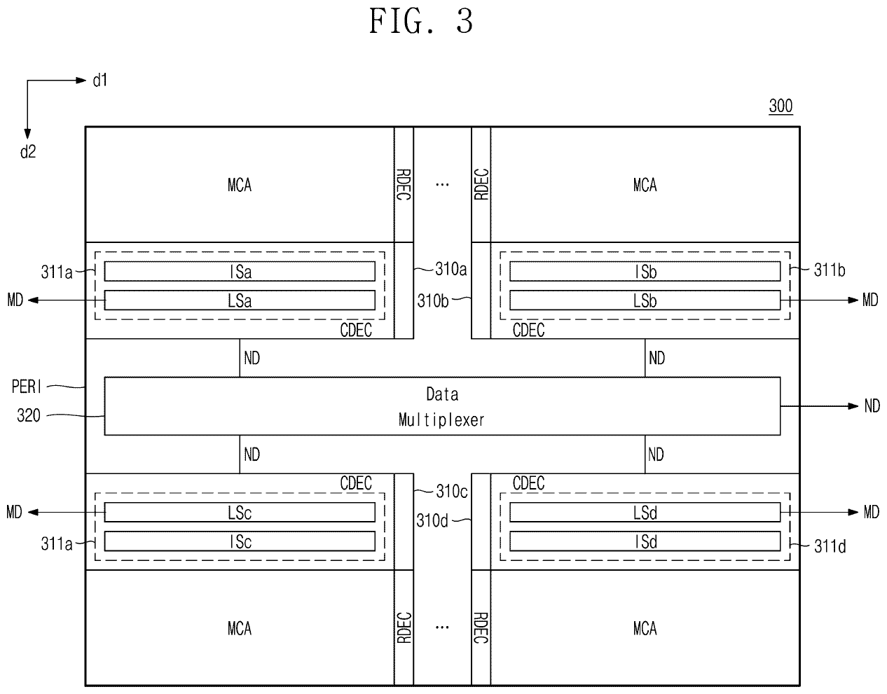

FIG. 3 is a diagram illustrating a memory device according to example implementations.

Referring to FIG. 3, a memory device 300 according to example implementations may include a plurality of banks 310a to 310d and a data multiplexer 320.

Each of the plurality of banks 310a to 310d may include a row decoder RDEC, a column decoder CDEC, and a memory cell array MCA. Each column decoder CDEC may include input/output sense amplifier stage ISa to ISd and logic stages LSa to LSd. The input/output sense amplifier stages ISa to ISd and the logic stages LSa to LSd may constitute multiplexer stages 311a to 311d.

According to example implementations, the number of the plurality of banks 310a to 310d may be determined depending on the capacity of the memory device 300. A portion of the plurality of banks 310a to 310d and the remaining banks may be arranged in a first direction d1 with a peripheral circuit region PERI interposed therebetween. The row decoder RDEC may extend in a second direction d2 and may be provided as many as the number of banks. The column decoder CDEC may extend in the first direction d1 and may be provided as many as the number of banks, similarly to the row decoder RDEC.

In the respective banks, a single bank may be enabled according to the above-described implementations (for example, FIGS. 1 and 2), and normal data ND or metadata MD may be output through the enabled single bank. In meta mode, the enabled single bank may output the metadata MD through the multiplexer stages 311a to 311d. In non-meta mode, the enabled single bank may output the normal data ND through the column decoder CDEC (for example, the input/output sense amplifier stage ISa to ISd), and the output normal data ND may be transmitted to the data multiplexer 320. The data multiplexer 320 may be included in the peripheral circuit region PERI and may multiplex normal data ND received from the plurality of banks and output the selected normal data ND.

According to the above-described implementations, the memory device 300 may include only a data multiplexer 320 for data multiplexing in the peripheral circuit region PERI, and a multiplexer for metadata MD may use the input/output sense amplifier stage ISa to ISd inside the column decoder CDEC. Accordingly, the implementation of an additional multiplexer in the peripheral circuit region PERI is not required, so that a chip size may be reduced.

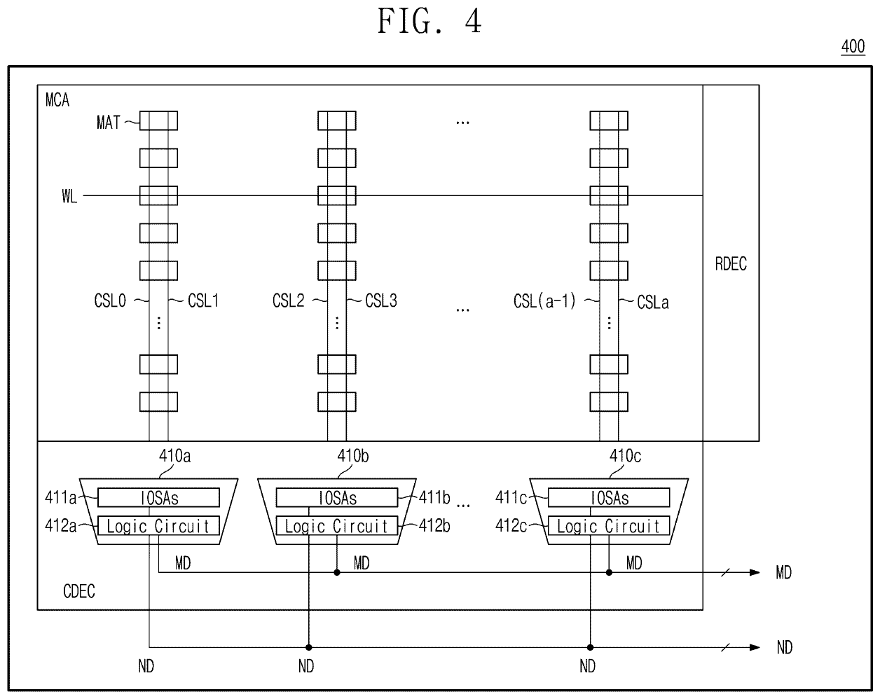

FIG. 4 is a diagram illustrating a bank according to example implementations.

Referring to FIG. 4, a bank 400 according to example implementations may include a row decoder RDEC, a column decoder CDEC, and a memory cell array MCA. The memory cell array MCA may include a plurality of mats MATs. A portion of wordlines WL and a portion of common select lines CSLs may be connected to each of the plurality of mats MATs. A mat may include memory cells arranged 2-dimensionally, and each of the memory cells may be connected to a single wordline WL, among a portion of the wordlines WL connected to the corresponding mat MAT, and a single common select line CSL, among a portion of the common select lines CSLs connected to the corresponding mat MAT. According to example implementations, MATs corresponding to a portion of the columns may store a parity bit corresponding to an error correction code (ECC).

Normal data ND or metadata MD may be read from the memory cell array MCA as a wordline WL is enabled through the row decoder RDEC and a common select line CSL is enabled through the column decoder CDEC. The illustrated common select lines CSL0 to CSLa may be common select lines that may be assigned per access through the column decoder CDEC, among the plurality of column select lines CSL connected to a mat MAT. Although not illustrated, x (where x is a positive integer) column select lines CSLs may be connected to a single column. In the case of FIG. 4, among x column select lines CSLs, two column select lines CSLs may be enabled. Alternatively, common select lines CSL in a number other than 2 may be enabled. In the case of FIG. 4, the number of CSLs that may be enabled per access to a single bank 400 may be a+1 (where “a” is a positive integer smaller than x).

In general, a bank 400 may read normal data ND from a mat MAT through the column select lines CSLs CSL0 to CSLa and transmit the read normal data ND to the column decoder CDEC. When the bank 400 operates in meta mode, the remaining column select lines except for a portion of the columns select lines CSL0 to CSLa may be disabled. The portion of column select lines CSLs may be column select lines CSLs assigned for metadata MD. For example, when the third column select line CSL2 is assigned for metadata MD, the metadata MD may be read through the third column select line CSL2 and then transmitted to the column decoder CDEC, and the remaining column select lines CSLs may be disabled.

The column decoder CDEC may include a plurality of metadata multiplexers 410a to 410c. According to example implementations, the number of the plurality of metadata multiplexers 410a to 410c may be equal to a width of metadata MD that may be read per access. For example, when the width of metadata MD is 16 bits, 16 metadata multiplexers 410a to 410c may be provided.

Each of the metadata multiplexers 410a to 410c may include a plurality of input/output sense amplifiers 411a to 411c and logic circuits 412a to 412c. Each of the plurality of input/output sense amplifiers 411a to 411c may be configured to amplify and output normal data ND and metadata MD. The logic circuits 412a to 412c may be connected to output terminals of the plurality of input/output sense amplifiers 411a to 411c and may be configured to output only metadata MD through a logical operation. According to example implementations, the number of the plurality of input/output sense amplifiers 411a to 411c included in one of the metadata multiplexers 410a to 410c may be x, the number of column select lines CSLs connected to a single column. Then, each input/output sense amplifier may correspond to a single column select line CSL.

The plurality of input/output sense amplifiers 411a to 411c may receive data, read from a mat MAT, through a column select line CSL and amplify and output the received data. In meta mode, an input/output sense amplifier corresponding to a column select line CSL assigned for metadata MD may amplify and output metadata MD read from an enabled column select line CSL. In addition, input/output sense amplifiers corresponding to the remaining column select lines CSLs may output a default value. Therefore, the logic circuits 412a to 412c may output metadata MD through a logic operation in which only the metadata MD may be selected from the outputs of the plurality of input/output sense amplifiers 411a to 411c, which include both metadata MD and a default value.

The metadata multiplexer 410a to 410c corresponding to each column may output multiplexed metadata MD. Ultimately, metadata MD output from a single bank 400 through the plurality of metadata multiplexers 410a to 410c may be output.

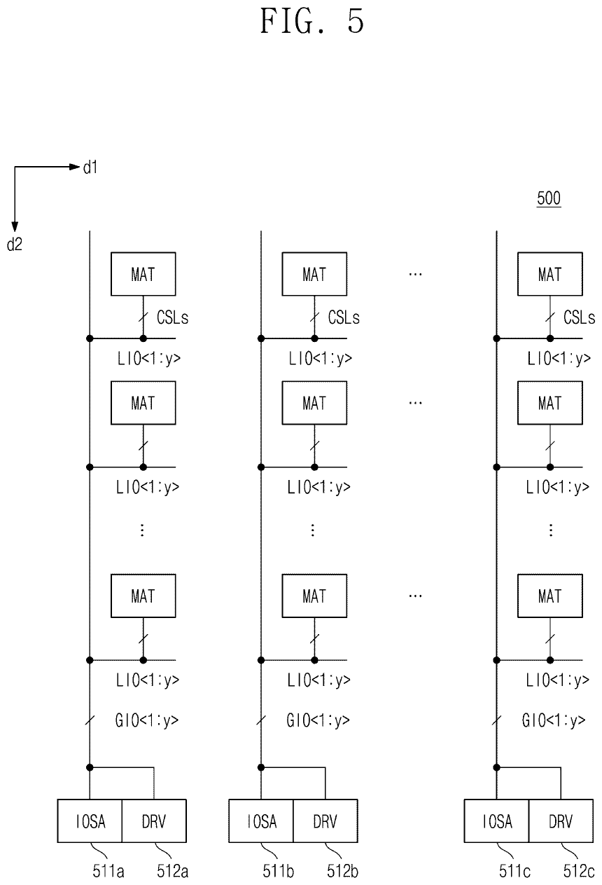

FIG. 5 is a diagram illustrating a bank array according to example implementations.

Referring to FIG. 5, a bank array 500 according to example implementations may include plurality of mats MATs. A plurality of mats MATs, arranged in a second direction d2 and connected to common global input/output lines GIO<1:y>, may be defined as the above-described columns or sub-arrays. The number y (where y is a positive integer) of global input/output lines GIO<1:y> connected to a single column may be determined based on a data input/output unit of a memory device, a prefetch size, a burst length, or the like.

Inputting and outputting data to each sub-array may be performed through the local input/output lines LIO<1:y> and the global input/output lines GIO<1:y>. Similarly, y local input/output lines LIO<1:y> may be provided. Depending on a write or read access, one or more column select lines CSLs connected to each sub-array may be enabled, and a mat within a sub-array and memory cells included in the mat may be selected through the enabled one or more column select lines CSLs.

For example, in the case of a read operation, data read from selected memory cells may be provided to the input/output sense amplifiers 511a to 511c through bitlines, the enabled column select line CSL, the local input/output lines LIO<1:y>, and the global input/output lines GIO<1:y>. The input/output sense amplifiers 511a to 511c may sense and amplify voltages of the global input/output lines GIO<1:y> based on bits output through the global input/output lines GIO<1:y>. The input/output sense amplifiers 511a to 511c, connected to the global lines of FIG. 5, may include a plurality of input/output sense amplifiers included in the above-described metadata multiplexer of FIG. 4.

According to example implementations, a portion of the column select lines CSLs may be assigned for metadata. In meta mode, the remaining column select lines CSLs except for the column select lines CSLs assigned for metadata may be disabled. The metadata may be transmitted to the input/output sense amplifiers 511a to 511c through the local input/output lines LIO<1:y> and global input/output lines GIO<1:y> connected to the column select lines CSLs assigned for metadata.

For example, in the case of a write operation, the driver 512a to 512c may transmit data to the memory cells through the global input/output lines GIO<1:y>, the local input/output lines LIO<1:y>, the enabled column select line CSL, and bitlines in response to a write signal.

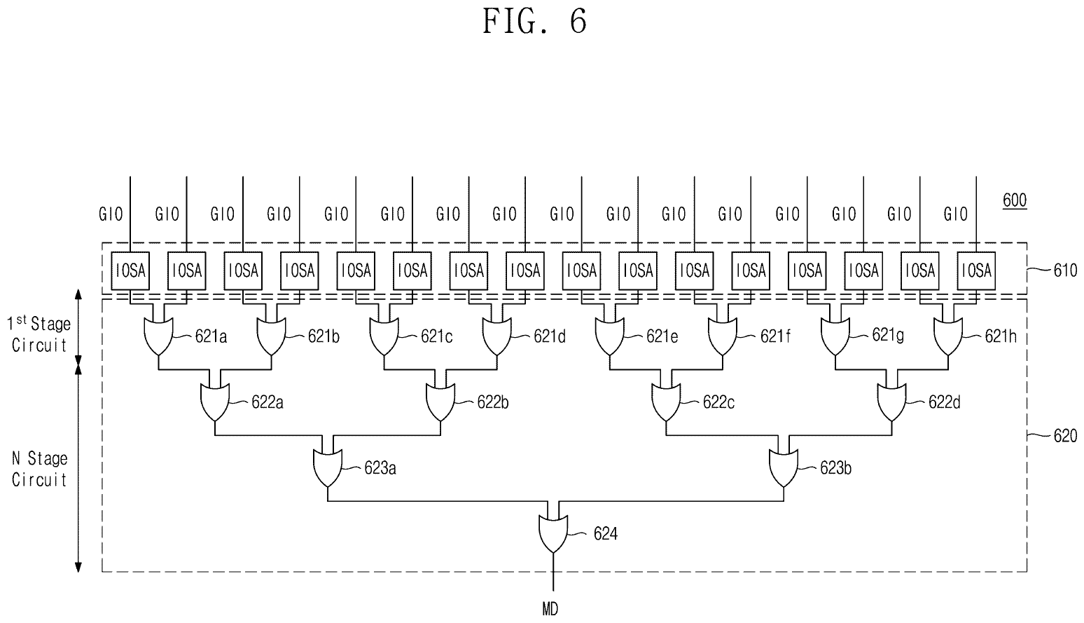

FIGS. 6 to 8 are diagrams illustrating a metadata multiplexer according to example implementations. In FIGS. 6 to 8, an example is provided in which 16 input/output sense amplifiers are provided. However, the number of input/output sense amplifiers that may be included in a single metadata multiplexer is not limited thereto and may be configured or set in various ways.

Referring to FIGS. 6 to 8, metadata multiplexer 600, 700, and 800 according to example implementations may include a plurality of input/output sense amplifiers 610, 710, and 810 and a plurality of logic circuits 620, 720, and 820, respectively. According to example implementations, the metadata multiplexer 600, 700, and 800 of FIGS. 6 to 8 may correspond to the metadata multiplexer 410a to 410c of FIG. 4 according to the above-described implementations, the multiple input/output sense amplifiers 610, 710, and 810 of FIGS. 6 to 8 may correspond to the multiple input/output sense amplifiers 411a to 411c of FIG. 4 according to the above-described implementations, and the logic circuit 620, 720, and 820 of FIGS. 6 to 8 may correspond to the logic circuit 412a to 412c of FIG. 4 according to the above-described implementations.

The plurality of input/output sense amplifiers 610, 710, and 810 may be connected to the plurality of global input/output lines GIO. For example, a global input/output line GIO connected to each input/output sense amplifier may be one of the global input/output line connected to the single column of FIG. 5.

According to example implementations, in meta mode, global input/output lines GIO corresponding to column select lines CSLs assigned for metadata MD, among the global input/output lines GIO, may transmit metadata MD. For example, one or more of the plurality of global input/output lines GIO may transmit metadata MD. An input/output sense amplifier, connected to the global input/output line GIO transmitting the metadata MD, may amplify and output the metadata MD. In addition, in meta mode, input/output sense amplifiers connected to the remaining global input/output lines GIO corresponding to remaining disabled column select lines CSLs may output a default value.

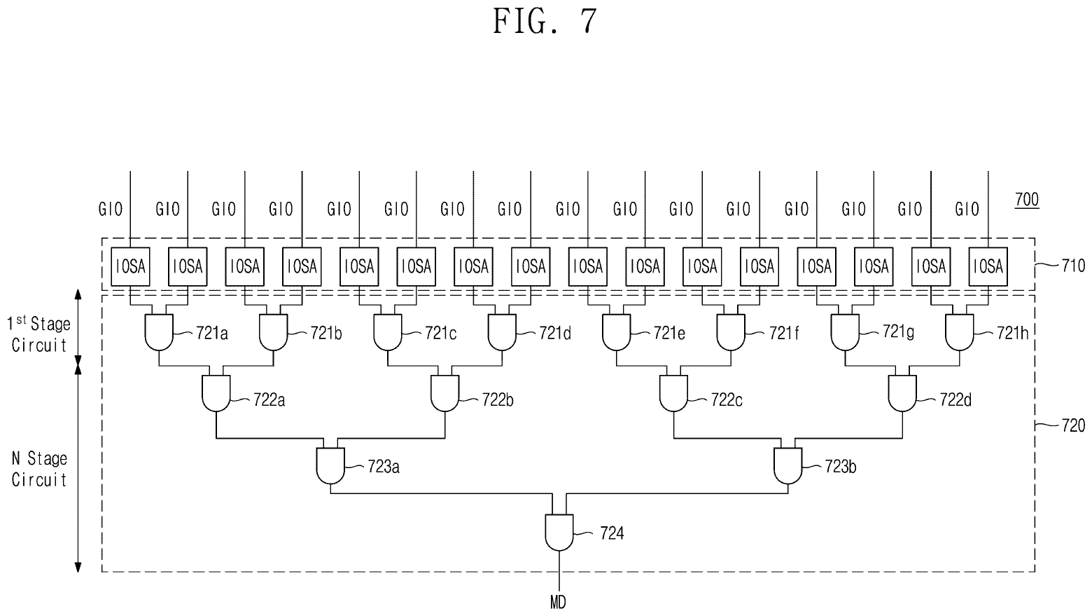

According to example implementations, each of the logic circuits 620 and 720 of FIGS. 6 and 7 may include a first stage circuit and a plurality of N stage circuits (where N is a positive integer greater than or equal to 2) connected to the first stage circuit, and N may be determined based on the number of input/output sense amplifiers. For example, in the case of FIGS. 6 and 7, N may include 2 to 4. The logic gates included in each circuit 620 and 720 may include various logic circuits that may perform a logical operation to select metadata MD from among input values.

The first stage circuit may include a plurality of first logic gates, respectively connected to output terminals of two input/output sense amplifiers among the plurality of input/output sense amplifiers. Each first logic gate may perform a logical operation on two values output from the two input/output sense amplifiers and provide a result of the logical operation to the N-stage circuit connected to the output terminal.

Each of the plurality of N stage circuits may include one or more N stage logic gates connected to output terminals of two (N−1) stage logic gates included in an (N−1) stage circuit corresponding to an input terminal. Similarly, each of the N stage logic gates may perform a logical operation on the two values output from two (N−1) logic gates of a previous stage and provide a result of the logical operation to the next stage. Finally, the N-stage circuit, may output metadata MD.

According to example implementations, a plurality of first logic gates 621a to 621h and one or more N stage logic gates 622a to 622d, 623a to 623b, and 624 may be configured as OR gates as illustrated in FIG. 6, based on one of the plurality of input/output sense amplifiers 610 outputting metadata MD and the remaining input/output sense amplifiers outputting a logic low value. For example, when the default value output by the input/output sense amplifier corresponding to the disabled CSL is set to be low, the logic gates included in the logic circuit may be configured as OR gates. Accordingly, each logic gate may select the metadata MD from the logic low value and metadata MD through an OR operation.

According to example implementations, a plurality of first logic gates 721a to 721h and one or more N stage logic gates 722a to 722d, 723a to 723b, and 724 may be configured as AND gates as illustrated in FIG. 7, based on one of the plurality of input/output sense amplifiers 710 outputting metadata MD and the remaining input/output sense amplifiers outputting a logic high value. For example, when the default value output by the input/output sense amplifier corresponding to the disabled CSL is set to be high, the logic gates included in the logic circuit may be configured as AND gates. Accordingly, each logic gate may select the metadata MD from the logic low value and the metadata MD through an AND operation.

According to the above-described implementations, the logic gates may be configured in various ways depending on a phase of the default value output by the input/output sense amplifier corresponding to the disabled CSL.

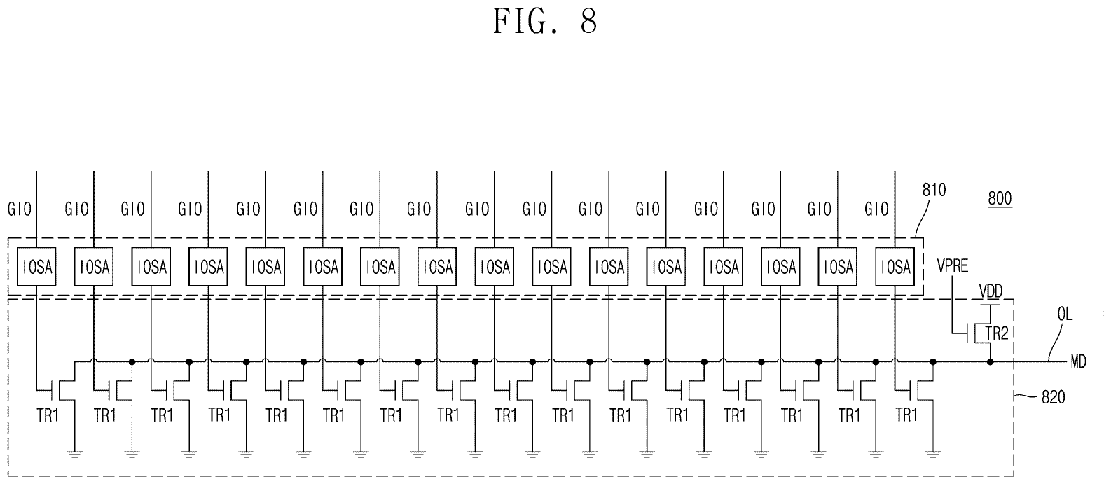

The logic circuit 820 according to example implementations may also be implemented as a wired logic circuit as illustrated in FIG. 8. For example, the logic circuit 820 may include a plurality of first transistors TR1 and a plurality of second transistors TR2. Each of the plurality of first transistors TR1 may have a gate connected to one of the plurality of input/output sense amplifiers 810, a source grounded, and a drain connected to an output line OL. For example, the drains of the plurality of first transistors TR1 may be commonly connected to the output line OL to output only the metadata MD, among the metadata MD and the default value output from the input/output sense amplifier, to the output line OL. The second transistor TR2 may have a source connected to the output line OL, a gate applied with a precharge voltage VPRE, and a drain applied with a power supply voltage VDD.

The second transistor TR2 may be turned on or turned off depending on the precharge voltage VPRE. When the second transistor TR2 is turned on, the output line OL may be precharged to a specific voltage. Among the plurality of first transistors TR1, a plurality of first transistors TR1 corresponding to the global input/output lines GIO connected to the disabled CSL may be turned off as a default value (for example a logic low value) is applied to the gate. In addition, the first transistor TR1 connected to the global input/output line GIO corresponding to the enabled CSL may be turned on as a voltage corresponding to metadata MD is applied to the gate.

When the metadata MD corresponds to a logic high value and the default value is a logic low value, the first transistor TR1 applied with a voltage corresponding to the metadata MD may be turned on and the remaining first transistors TR1 may be turned off, so that the output line OL may be connected to the ground of the first transistor TR1 and the voltage of the output line OL may become a ground voltage. Alternatively, when the metadata MD corresponds to a logic low value, the voltage of the output line OL may be maintained as if all first transistors TR1 are turned off. Accordingly, the logic circuit 820 may provide an output value based on the metadata MD.

According to example implementations, the first transistor TR1 and the second transistor TR2 may be implemented as PMOS transistors as well as NMOS transistors as illustrated.

According to the above-described implementations, the metadata multiplexer may be configured to multiplex metadata MD by adding only a logic circuit to the input/output sense amplifiers included in the column decoder. Accordingly, an additional circuit for multiplexing the metadata MD may not be provided in the peripheral circuit region of the memory device. As a result, a chip size overhead may be reduced.

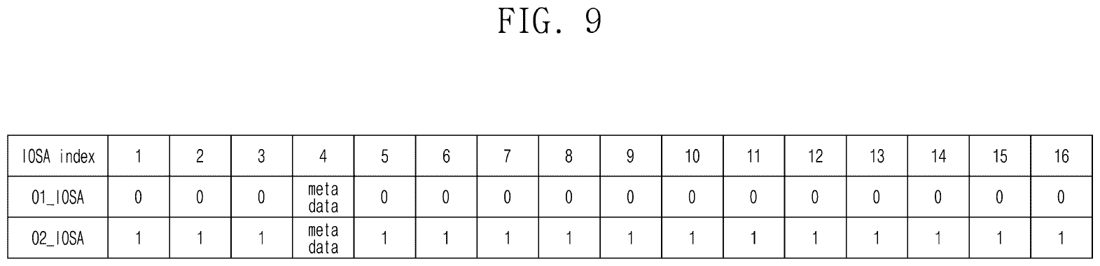

FIG. 9 is a diagram illustrating a combination of outputs of input/output sense amplifiers included in a metadata multiplexer according to example implementations. In FIG. 9, an example is provided in which a fourth input/output sense amplifier outputs metadata (for example, a common select line CSL corresponding to the fourth input/output sense amplifier is enabled and the remaining common select lines CSLs are disabled).

Referring to FIG. 9, when a default value is set to be low, a first output value O1_IOSA may all be low except for an output for the fourth input/output sense amplifier. In addition, the output for the fourth input/output sense amplifier may be metadata of a positive phase. When the logic circuit is configured as an OR gate, a result of multiplexing an output combination of the first output value may be metadata.

Alternatively, when the default value is set to be high, the second output value O2_IOSA may all be high except for the output for the fourth input/output sense amplifier. In addition, the output for the fourth input/output sense amplifier may be metadata of an inverted phase. When the logic circuit is configured as an AND gate, a result of multiplexing an output combination of the second output value may be metadata of an inverted phase.

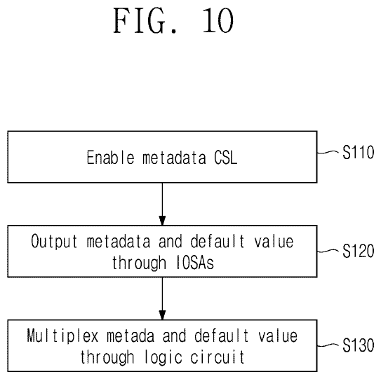

FIG. 10 is a flowchart illustrating a method of operating a memory device according to example implementations.

Referring to FIG. 10, in operation S110, the memory device may enable a common select line assigned for metadata. For example, the memory device may enable a common select line CSL for metadata and disable the remaining common select lines CSLs based on a command/address signal.

In operation S120, the memory device may output metadata and a default value through input/output sense amplifiers. An input/output sense amplifier corresponding to the enabled common select line CSL for metadata may output metadata, and an input/output sense amplifier corresponding to the disabled common select line CSL may output a default value.

In operation S130, the memory device may multiplex the metadata and the default value through a logic circuit and output the metadata. For example, the memory device may select metadata through a logical operation such as an OR operation and an AND operation based on the phase of the default value.

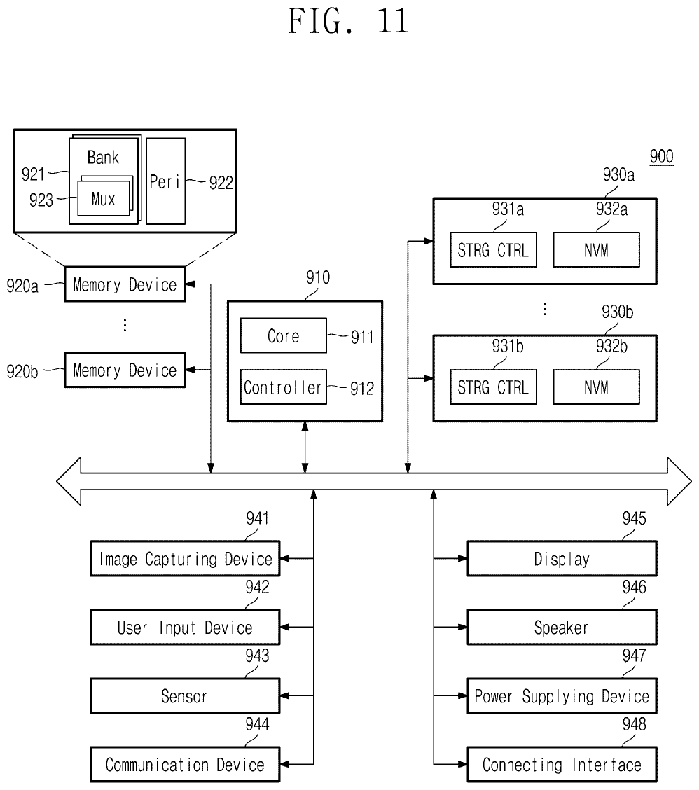

FIG. 11 is a diagram illustrating a system according to example implementations.

Referring to FIG. 11, a system 900 may be a mobile system such as a mobile phone, a smartphone, a tablet personal computer (PC), a wearable device, a healthcare device, or an Internet of Things (IoT) device. Alternatively, the system 900 may be a personal computer, a laptop computer, a server, a media player, or an automotive device such as a navigation device, as well as the mobile system.

In an example implementation, the system 900 may include a main processor 910, memories 920a to 920b, and storage devices 930a and 930b, and may further include at least one of an image capturing device 941, a user input device 942, a sensor 943, a communication device 944, a display 945, a speaker 946, a power supply device 947, and a connection interface 948.

The main processor 910 may control the overall operation of the system 900, for example, operations of other components included in the system 900. The main processor 910 may be implemented as a general-purpose processor, a specific-purpose processor, or an application processor.

The main processor 910 may include one or more cores 911, and may further include a controller 912 to control the memories 920a to 920b and/or the storage devices 930a and 930b. In an example implementation, the main processor 910 may further include an accelerator, a specific-purpose circuit for high-speed data processing such as artificial intelligence (AI) data processing.

The memories 920a to 920b may be used as a main memory device of the system 900 and may include nonvolatile memories such as a static random access memory (SRAM) and/or a dynamic random access memory (DRAM). The memories 920a to 920b may be implemented within the same package as the main processor 910.

According to example implementations, each of the memories 920a to 920b may include the plurality of banks 921 and peripheral circuit areas 922 according to the above-described implementations (for example, FIGS. 1 to 8). Each of the plurality of banks 921 may include a plurality of metadata multiplexers 923. The metadata multiplexer 923 may be provided in a column decoder included in the bank 921 to multiplex and output only metadata from among the metadata and the default value. As described above, the metadata multiplexer 923 may be provided in the bank 921, rather than in a peripheral circuit region 922, so that a chip size may be reduced compared to the case in which the metadata multiplexer 923 is added to the peripheral circuit region 922.

Each of the storage devices 930a and 930b may function as a nonvolatile storage device storing data regardless of whether power is supplied, and may have relatively large storage capacity compared to the memory. The storage devices 930a and 930b may include storage controllers 931a and 931b and nonvolatile memories (NVMs) 932a and 932b storing data under the control of the storage controllers 931a and 931b, respectively. The NVMs 932a and 932b may include a flash memory having a two-dimensional (2D) structure or a three-dimensional vertical NAND (3D V-NAND) structure but may also include other types of nonvolatile memory such as a phase-change RAM (PRAM) and/or a resistive RAM (RRAM).

The storage devices 930a and 930b may be included in the system 900 while being physically separated from the main processor 910 or may be implemented in the same package as the main processor 910. In addition, each of the storage devices 930a and 930b may be in the form of a solid-state drive (SSD) or a memory card to be removably coupled to other components of the system 900 through an interface such as a connection interface 948 to be described later. Each of the storage devices 930a and 930b may be a device to which the standard protocol is applied, such as such as a universal flash storage (UFS), an embedded multimedia card (eMMC), or a nonvolatile memory express (NVMe), but example implementations are not limited thereto.

The image capturing device 941 may capture still images or videos and may be a camera, a camcorder, and/or a webcam.

The user input device 942 may receive various types of data input from a user of the system 900, and may be a touchpad, a keypad, a keyboard, a mouse, and/or a microphone.

The sensor 943 may detect various types of physical quantities that may be obtained from the outside of the system 900 and may convert the detected physical quantities into electrical signals. The sensor 943 may include a temperature sensor, a pressure sensor, an illuminance sensor, a position sensor, an acceleration sensor, a biosensor, and/or a gyroscope sensor.

The communication device 944 may transmit and receive signals between other devices outside the system 900 based on various communication protocols. The communication device 944 may be implemented to include an antenna, a transceiver, and/or a modem.

The display 945 and speaker 946 may function as output devices to output visual information and auditory information to the user of the system 900, respectively.

The power supply device 947 may appropriately convert power supplied from an internal battery and/or external power, and may supply the converted power to each component of the system 900.

The connection interface 948 may provide a connection between the system 900 and an external device connected to the system 900 to exchange data with the system 900. The connection interface 948 may be implemented in various interface schemes such as an advanced technology attachment (ATA), a serial ATA (SATA), an external SATA (e-SATA), a small computer system interface (SCSI), a serial attached SCSI (SAS), a peripheral component interconnect (PCI), a PCI express (PCle), an NVMe, an IEEE 1394, a universal serial bus (USB), a secure digital (SD) card interface, a multimedia card (MMC) interface, an embedded MMC (eMMC) interface, a universal flash storage (UFS) interface, an embedded UFS (eUFS) interface, or a compact flash (CF) card interface.

The system 900 according to the above-described implementations may reduce the chip size of the memory 920a to 920b by providing the metadata multiplexer 923 for multiplexing metadata in the bank 921, rather than in the peripheral circuit region 922.

As set forth above, according to example implementations, a multiplexer for multiplexing metadata and a memory device including the same may be provided.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations have been shown and described above, it will be apparent to those skilled in the art that modifications and variations could be made without departing from the scope of the present inventive concept as defined by the appended claims.

What is claimed is:

1. A multiplexer comprising:
a plurality of input/output (I/O) sense amplifiers, each I/O sense amplifier of the plurality of I/O sense amplifiers comprising an output terminal and configured to amplify and output normal data and metadata; and
a logic circuit connected to the output terminals of the plurality of I/O sense amplifiers and configured to output the metadata through a logical operation.

2. The multiplexer of claim 1, wherein
the plurality of I/O sense amplifiers are connected to a plurality of global I/O lines.

3. The multiplexer of claim 2, wherein
one or more first global I/O lines of the plurality of global I/O lines are configured to transmit the metadata in a specific operation mode.

4. The multiplexer of claim 3, wherein
the plurality of I/O sense amplifiers include I/O sense amplifiers that are connected to second global I/O lines of the plurality of global I/O lines and that are configured to output a default value in the specific operation mode.

5. The multiplexer of claim 1, wherein
the logic circuit comprises:
a first stage circuit comprising a plurality of first logic gates, each connected to output terminals of two I/O sense amplifiers among the plurality of I/O sense amplifiers; and
a plurality of N stage circuits (where N is a positive integer greater than or equal to 2) connected to the first stage circuit.

6. The multiplexer of claim 5, wherein
each of the plurality of N stage circuits comprises:
one or more N^{th} logic gates connected to output terminals of two (N−1)^{th} logic gates included in an (N−1) stage circuit.

7. The multiplexer of claim 6, wherein
the plurality of first logic gates and the one or more N^{th} logic gates are configured as OR gates, based on a first I/O sense amplifier of the plurality of I/O sense amplifiers being configured to output the metadata and a second I/O sense amplifier of the plurality of I/O sense amplifiers being configured to output a logic low value.

8. The multiplexer of claim 6, wherein
the plurality of first logic gates and the one or more N^{th} logic gates are configured as AND gates, based on a first I/O sense amplifier of the plurality of I/O sense amplifiers being configured to output the metadata and a second I/O sense amplifier of the plurality of I/O sense amplifiers being configured to output a logic high value.

9. The multiplexer of claim 1, wherein
the logic circuit comprises:
a plurality of first transistors, each transistor having a gate connected to one of the plurality of I/O sense amplifiers, a source grounded, and a drain connected to an output line; and
a second transistor having a source connected to the output line and a gate applied with a precharge voltage.

10. A memory device comprising:
a plurality of banks, each comprising a memory cell array and a column decoder; and
a control logic circuit configured to provide a column address to the column decoder, the column decoder comprising:
an input/output (I/O) sense amplifier stage configured to amplify and output normal data and metadata provided from a selected column select line, among a plurality of column select line connected to the memory cell array, in response to the column address; and
a logic stage connected to an output terminal of the I/O sense amplifier stage and configured to output the metadata through a logical operation.

11. The memory device of claim 10, wherein
the I/O sense amplifier stage comprises:
a plurality of I/O sense amplifiers connected to a plurality of global I/O lines corresponding to the plurality of common select lines.

12. The memory device of claim 11, wherein
one or more first global I/O lines of the plurality of global I/O lines are configured to transmit the metadata in a specific operation mode, and
input/output sense amplifiers that are connected to second global I/O lines of the plurality of global I/O lines, among the plurality of I/O sense amplifiers, are configured to output a default value in the specific operation mode.

13. The memory device of claim 11, wherein
the logic stage comprises:
a first stage circuit comprising a plurality of first logic gates, each connected to output terminals of two I/O sense amplifiers, among the plurality of I/O sense amplifiers; and
a plurality of N stage circuits (where N is a positive integer greater than or equal to 2) connected to the first stage circuit.

14. The memory device of claim 10, wherein
at least a portion of the plurality of common select lines are assigned for the metadata.

15. The memory device of claim 14, wherein
the control logic circuit is configured to enable at least a first portion of the plurality of common select lines and is configured to disable a second portion of the plurality of common select lines, in a specific operation mode.

16. A memory device comprising:
a plurality of banks, each comprising a memory cell array and a column decoder; and
a data multiplexer configured to multiplex normal data output from the plurality of banks,
wherein the column decoder comprises:
an input/output (I/O) sense amplifier stage configured to amplify and output the normal data and metadata provided from a selected common select line, among a plurality of column select lines connected to the memory cell array; and
a logic stage connected to an output terminal of the I/O sense amplifier stage and configured to output only the metadata through a logical operation.

17. The memory device of claim 16, wherein
the data multiplexer is included in a peripheral circuit region.

18. The memory device of claim 16, wherein
the I/O sense amplifier stage comprises:
a plurality of I/O sense amplifiers that are connected to a plurality of global I/O lines corresponding to the plurality of common select lines.

19. The memory device of claim 18, wherein
one or more first global I/O lines of the plurality of global I/O lines are configured to transmit the metadata in a specific operation mode, and
input/output sense amplifiers connected to second global I/O lines of the plurality of global I/O lines, among the plurality of I/O sense amplifiers, are configured to output a default value in the specific operation mode.

20. The memory device of claim 18, wherein
the logic stage comprises:
a first stage circuit comprising a plurality of first logic gates, each connected to output terminals of two I/O sense amplifiers, among the plurality of I/O sense amplifiers; and
a plurality of N stage circuits (where N is a positive integer greater than or equal to 2) connected to the first stage circuit.
